(19) United States
(12) Patent Application Publication
(10) Pub. No.: US 2017/0140972 A1
(43) Pub. Date: May 18, 2017

(54) LAMINATED BODY AND SEMICONDUCTOR DEVICE MANUFACTURING METHOD

(71) Applicant: NITTO DENKO CORPORATION, Osaka (JP)

(72) Inventors: Ryuichi KIMURA, Ibaraki-shi (JP); Yuichiro SHISHIDO, Ibaraki-shi (JP); Naohide TAKAMOTO, Ibaraki-shi (JP)

(73) Assignee: NITTO DENKO CORPORATION, Osaka (JP)

(21) Appl. No.: 15/349,154

(22) Filed: Nov. 11, 2016

(30) Foreign Application Priority Data
Nov. 13, 2015 (JP) 2015-222915

(51) Int. Cl. H01L 21/683; H01L 23/31; H01L 21/78

(52) U.S. Cl. CPC H01L 21/6836; H01L 21/78; H01L 23/3171; H01L 2221/68327; H01L 2221/68322; H01L 2221/68377

(57) ABSTRACT

A laminated body comprising a dicing sheet and a semiconductor backside protective film, in which the dicing sheet comprises a base layer and an adhesive layer arranged over the base layer, the semiconductor backside protective film is arranged over the adhesive layer, the dicing sheet is provided with a property such that application of heat thereto causes contraction thereof, and with a property such that heat treatment thereof for one minute at 100° C. causes a second length in an MD direction following heat treatment to be not greater than 95% when expressed as a percentage such that a first length in the MD direction prior to heat treatment is taken to be 100%.

### TECHNICAL FIELD

The present invention relates to a laminated body and a semiconductor device manufacturing method.

### BACKGROUND ART

Semiconductor backside protective films serve to reduce warpage of semiconductor wafers and to protect the backsides thereof and so forth. Methods in which semiconductor backside protective film and a dicing sheet are handled in integral fashion are known.

### PRIOR ART REFERENCES

### Patent References

PATENT REFERENCE NO. 1: Japanese Patent Application Publication Kokai No. 2010-199541

### SUMMARY OF INVENTION

### Problem to be Solved by Invention

As shown in FIG. 12, wafer 904—comprising semiconductor chips 905A, 905B, 905C, . . . , 905H (hereinafter sometimes referred to collectively as “semiconductor chips 905”) and modified regions 941—is secured to semiconductor backside protective film 903; as shown in FIG. 13, dicing sheet 901—comprising base layer 911 and adhesive layer 912—is expanded to cause dicing of wafer 904, this being initiated from modified regions 941; and as shown in FIG. 14, subsequent de-expansion causes occurrence of slack at peripheral portion 912b. If the slack at peripheral portion 912b is left the way it is, there may be occurrence of contact between semiconductor chip 905A and semiconductor chip 905B, semiconductor chip 905B and semiconductor chip 905C, . . . , and semiconductor chip 905G and semiconductor chip 905H. If semiconductor chips 905 come in contact with each other, it may be impossible for pick-up of semiconductor chips 905 to be carried out such that these are picked up one at a time.

It is an object of the present invention to provide a laminated body that makes it possible for the backside of a semiconductor chip to be furnished with a protective film—post-dicing semiconductor backside protective film—and that makes it possible to prevent semiconductor chips from coming in contact with each other. It is also an object of the present invention to provide a method for manufacturing a semiconductor device that makes it possible for the backside of a semiconductor chip to be furnished with a protective film, and that makes it possible to prevent semiconductor chips from coming in contact with each other.

### Means for Solving Problem

The present invention relates to a laminated body comprising a dicing sheet and a semiconductor backside protective film. The dicing sheet comprises a base layer and an adhesive layer arranged over the base layer. The semiconductor backside protective film is arranged over the adhesive layer. The dicing sheet is provided with a property such that application of heat thereto causes contraction thereof. The dicing sheet is provided with a property such that heat treatment thereof for one minute at 100° C. causes a second length in an MD direction following heat treatment to be not greater than 95% when expressed as a percentage such that a first length in the MD direction prior to heat treatment is taken to be 100% A laminated body in accordance with the present invention may make it possible to prevent semiconductor chips from coming in contact with each other. This is so because heating causes removal of slack. A laminated body in accordance with the present invention may make it possible for the backside of a semiconductor chip to be furnished with post-dicing semiconductor backside protective film.

The present invention also relates to a semiconductor device manufacturing method. A semiconductor device manufacturing method in accordance with the present invention comprises an Operation (A) in which a pre-expansion body is prepared. The pre-expansion body comprises a laminated body and a pre-dicing wafer which is secured to semiconductor backside protective film at the laminated body. The pre-dicing wafer has modified regions. A semiconductor device manufacturing method in accordance with the present invention further comprises an Operation (B) in which expansion of a dicing sheet causes dicing of the pre-dicing wafer to be carried out, this being initiated from the modified regions. An adhesive layer at the dicing sheet comprises a central portion that is in contact with the semiconductor backside protective film, and a peripheral portion that is arranged peripherally with respect to the central portion. A semiconductor device manufacturing method in accordance with the present invention further comprises an Operation (C) in which, following Operation (B), the peripheral portion is heated.

### BRIEF DESCRIPTION OF DRAWINGS

FIG. 1 Schematic sectional diagram showing a laminated body.

FIG. 2 Schematic sectional diagram showing an operation for manufacturing a semiconductor device.

FIG. 3 Schematic sectional diagram showing an operation for manufacturing a semiconductor device.

FIG. 4 Schematic sectional diagram showing an operation for manufacturing a semiconductor device.

FIG. 5 Schematic sectional diagram showing an operation for manufacturing a semiconductor device.

FIG. 6 Schematic sectional diagram showing an operation for manufacturing a semiconductor device.

FIG. 7 Schematic sectional diagram showing an operation for manufacturing a semiconductor device.

FIG. 8 Schematic sectional diagram showing an operation for manufacturing a semiconductor device.

FIG. 9 Schematic sectional diagram showing an operation for manufacturing a semiconductor device.

FIG. 10 Schematic sectional diagram showing an operation for manufacturing a semiconductor device.

FIG. 11 Schematic perspective view of a test piece.

FIG. 12 Schematic sectional diagram showing the situation before dicing sheet expansion.

FIG. 13 Schematic sectional diagram showing the situation during dicing sheet expansion.

FIG. 14 Schematic sectional diagram showing the situation after dicing sheet expansion.

### EMBODIMENTS FOR CARRYING OUT INVENTION

Although the present invention is described in detail below in terms of embodiments, it should be understood that the present invention is not limited only to these embodiments.

### Embodiment 1

### —Laminated Body 10—

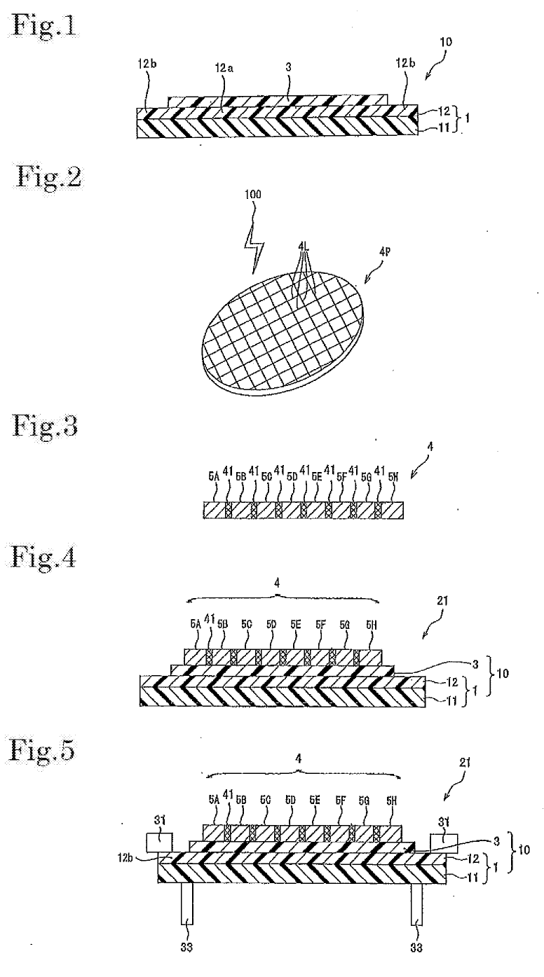

As shown in FIG. 1, laminated body 10 comprises dicing sheet 1 and semiconductor backside protective film 3 which is arranged over dicing sheet 1.

### —Dicing Sheet 1—

Dicing sheet 1 comprises base layer 11 and adhesive layer 12 arranged over base layer 11. Adhesive layer 12 comprises central portion 12a which is in contact with semiconductor backside protective film 3, and peripheral portion 12b which is arranged peripherally with respect to central portion 12a. Central portion 12a is cured. Peripheral portion 12b has a property such that it may be cured by means of an energy beam. As energy beam, ultraviolet beams and the like may be cited as examples. Peripheral portion 12b is not in contact with semiconductor backside protective film 3.

Dicing sheet 1 is provided with a property such that it contracts as a result of application of heat. Dicing sheet 1 is further provided with the following property. This is that upon being subjected to heat treatment for one minute at 100° C., a second length in the MD direction (machine direction) following heat treatment should not be greater than 95% when expressed as a percentage such that a first length in the MD direction prior to heat treatment is taken to be 100%. Because this is not greater than 95%, it is possible to cause slack to be removed as a result of heating, making it possible to prevent semiconductor chips from coming in contact with each other. It is preferred that the second length be not greater than 94% expressed as a percentage such that the first length is taken to be 100%. The lower limit of the range in values for the second length might, for example, be 50% when expressed as a percentage such that the first length is taken to be 100%.

The ratio of the second length to the first length may be controlled by means of material(s) employed at base layer 11 and method(s) employed to form base layer 11. The method(s) employed to form base layer 11 will have a large effect thereon. For example, the ratio of the second length to the first length may be reduced by stretching base layer 11.

It is preferred that dicing sheet 1 be provided with the following property. This is that upon being made to experience an elongation of 3% in the MD direction at 23° C., it is preferred that tensile stress be not less than 1 N/mm². When this is not less than 1 N/mm², it will be possible to increase the spacing between semiconductor chips such that the semiconductor wafer can be diced. This is so because during dicing of the semiconductor wafer a suitable tensile stress will act thereon. Furthermore, it will be possible to maintain the spacing that exists between semiconductor chips. The upper limit of the range in values for the tensile stress when this is made to experience an elongation of 3% in the MD direction at 23° C. might, for example, be 15 N/mm².

It is preferred that dicing sheet 1 be provided with the following property. This is that upon being made to experience an elongation of 6% in the MD direction at 23° C., it is preferred that tensile stress be not less than 1.5 N/mm². When this is not less than 1.5 N/mm², it will be possible to increase the spacing between semiconductor chips such that the semiconductor wafer can be diced. This is so because during dicing of the semiconductor wafer a suitable tensile stress will act thereon. Furthermore, it will be possible to maintain the spacing that exists between semiconductor chips. The upper limit of the range in values for the tensile stress when this is made to experience an elongation of 6% in the MD direction at 23° C. might, for example, be 20 N/mm².

It is preferred that thickness of dicing sheet 1 be not less than 40 μm, and more preferred that this be not less than 60 μm. And it is preferred that thickness of dicing sheet 1 be not greater than 200 μm, and more preferred that this be not greater than 180 μm.

It is preferred that thickness of base layer 11 be not less than 50%, and more preferred that this be not less than 70%, when expressed as a percentage such that the thickness of dicing sheet 1 is taken to be 100%. And it is preferred that thickness of base layer 11 be not greater than 98%, and more preferred that this be not less than 95%.

Base layer 11 might, for example, be polyethylene terephthalate film, polyethylene film, polystyrene film, polypropylene film, polyamide film, polyurethane film, polyvinylidene chloride film, polyvinyl chloride film, ethylene-vinyl acetate copolymer film, ethylene-acrylic acid ester copolymer film, polyvinyl chloride film, and/or the like. Any of these may be used in the form of unoriented film, uniaxially oriented film, biaxially oriented film, and/or the like. Of these, unoriented film is preferred due to its lack of anisotropy. Base layer 11 might be single-layered, multilayered, and/or the like.

To increase retention and adhesion to adjacent layer(s) and so forth, surface(s) of base layer 11 may be subjected to customary treatment(s); for example, chromic acid treatment, exposure to ozone, exposure to flame, exposure to high-voltage electricity, ionizing radiation treatment and/or other such chemical and/or physical treatment, and/or coating with primer(s) (e.g., the adhesive substance(s) described below) may be carried out.

The adhesive layer 12 is formed of a adhesive and has adhesiveness. Such an adhesive is not particularly restricted and can be suitably selected among known adhesives. Specifically, as the adhesive, a adhesive having the above-mentioned characteristics can be suitably selected and used among known adhesives such as acrylic adhesives, rubber-based adhesives, vinyl alkyl ether-based adhesives, silicone-based adhesives, polyester-based adhesives, polyamide-based adhesives, urethane-based adhesives, fluorine-based adhesives, styrene-diene block copolymer-based adhesives, and creep characteristic-improving adhesives in which a heat-meltable resin having a melting point of about 200.degree. C. or lower is mixed into these adhesives (see, e.g., JP-A-56-61468, JP-A-61-174857, JP-A-63-17981, JP-A-56-13040, etc.). Moreover, as the adhesives, radiation-curable adhesives (or energy ray-curable adhesives) or heat-expandable adhesives can be also used. The adhesive may be employed singly or in a combination of two or more kinds.

In the invention, as the adhesive, acrylic adhesives and rubber-based adhesives can be suitably used and particularly, acrylic adhesives are suitable. As the acrylic adhesives, there may be mentioned acrylic adhesives in which an acrylic polymer (homopolymer or copolymer) using one or more alkyl (meth)acrylates ((meth)acrylic acid alkyl ester) as monomer components is used as the base polymer.

Examples of the alkyl(meth)acrylates in the above-mentioned acrylic adhesives include alkyl(meth)acrylates such as methyl(meth)acrylate, ethyl (meth)acrylate, propyl(meth)acrylate, isopropyl(meth)acrylate, butyl(meth)acrylate, isobutyl(meth)acrylate, s-butyl(meth)acrylate, t-butyl(meth)acrylate, pentyl (meth)acrylate, hexyl(meth)acrylate, heptyl(meth)acrylate, octyl(meth)acrylate, 2-ethylhexyl(meth)acrylate, isooctyl(meth)acrylate, nonyl(meth)acrylate, isononyl (meth)acrylate, decyl(meth)acrylate, isodecyl(meth)acrylate, undecyl(meth)acrylate, dodecyl(meth)acrylate, tridecyl(meth)acrylate, tetradecyl(meth)acrylate, pentadecyl (meth)acrylate, hexadecyl(meth)acrylate, heptadecyl(meth)acrylate, octadecyl (meth)acrylate, nonadecyl(meth)acrylate, and eicosyl(meth)acrylate. As the alkyl (meth)acrylates, alkyl(meth)acrylates having 4 to 18 carbon atoms are suitable. Incidentally, the alkyl group of the alkyl(meth)acrylate may be linear or branched.

The above-mentioned acrylic polymer may contain units corresponding to other monomer components (copolymerizable monomer components) polymerizable with the above-mentioned alkyl(meth)acrylates for the purpose of modifying cohesive force, heat resistance, crosslinking ability, and the like. Examples of such copolymerizable monomer components include carboxyl group-containing monomers such as (meth)acrylic acid (acrylic acid or methacrylic acid), carboxyethyl acrylate, carboxypentyl acrylate, itaconic acid, maleic acid, fumaric acid, and crotonic acid; acid anhydride group-containing monomers such as maleic anhydride and itaconic anhydride; hydroxyl group-containing monomers such as hydroxyethyl(meth)acrylate, hydroxypropyl(meth)acrylate, hydroxybutyl(meth)acrylate, hydroxyhexyl (meth)acrylate, hydroxyoctyl(meth)acrylate, hydroxydecyl(meth)acrylate, hydroxylauryl(meth)acrylate, and (4-hydroxymethylcyclohexyl)methyl methacrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group-containing monomers such as 2-hydroxyethylacryloyl phosphate; (N-substituted)amide-based monomers such as (meth)acrylamide, N,N-dimethyl(meth)acrylamide, N-butyl(meth)acrylamide, N-methylol(meth)acrylamide, and N-methylolpropane(meth)acrylamide; aminoalkyl(meth)acrylate-based monomers such as aminoethyl(meth)acrylate, N,N-dimethylaminoethyl(meth)acrylate, and t-butylamino ethyl(meth)acrylate; alkoxyalkyl(meth)acrylate-based monomers such as methoxyethyl(meth)acrylate and ethoxyethyl(meth)acrylate; cyanoacrylate monomers such as acrylonitrile and methacrylonitrile; epoxy group-containing acrylic monomers such as glycidyl(meth)acrylate; styrene-based monomers such as styrene and .alpha.-methylstyrene; vinyl ester-based monomers such as vinyl acetate and vinyl propionate; olefin-based monomers such as isoprene, butadiene, and isobutylene; vinyl ether-based monomers such as vinyl ether; nitrogen-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, and N-vinylcaprolactam; maleimide-based monomers such as N-cyclohexylmaleimide, N-isopropylmaleimide, N-laurylmaleimide, and N-phenylmaleimide; itaconimide-based monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide-based monomers such as N-(meth)acryloyloxymethylenesuccinimide, N-(meth)acryloyl-6-oxyhexamethylenesuccinimide, and N-(meth)acryloyl-8-oxyoctamethylenesuccinimide; glycol-based acrylic ester monomers such as polyethylene glycol (meth)acrylate, polypropylene glycol (meth)acrylate, methoxyethylene glycol (meth)acrylate, and methoxypolypropylene glycol (meth)acrylate; acrylic acid ester-based monomers having a heterocycle, a halogen atom, a silicon atom, or the like, such as tetrahydrofurfuryl(meth)acrylate, fluorine (meth)acrylate, and silicone (meth)acrylate; polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxy acrylate, polyester acrylate, urethane acrylate, divinylbenzene, butyl di(meth)acrylate, and hexyl di(meth)acrylate; and the like. These copolymerizable monomer components may be employed singly or in a combination of two or more kinds.

In the case that a radiation-curable adhesive (or an energy ray-curable adhesive) is used as a adhesive, examples of the radiation-curable adhesive (composition) include internal radiation-curable adhesives in which a polymer having a radically reactive carbon-carbon double bond in the polymer side chain or main chain is used as the base polymer, radiation-curable adhesives in which a UV curable monomer component or oligomer component is blended into the adhesive, and the like. Moreover, in the case that the heat-expandable adhesive is used as the adhesive, there may be mentioned heat-expandable adhesives containing a adhesive and a foaming agent (particularly, heat-expandable microsphere) and the like as the heat-expandable adhesive.

In the invention, the adhesive layer 12 may contain various additives (e.g., a tackifying resin, a coloring agent, a thickener, an extender, a filler, a plasticizer, an antiaging agent, an antioxidant, a surfactant, a crosslinking agent, etc.) within the range where the advantages of the invention are not impaired.

The crosslinking agent is not particularly restricted and known crosslinking agents can be used. Specifically, as the crosslinking agent, not only isocyanate-based crosslinking agents, epoxy-based crosslinking agents, melamine-based crosslinking agents, and peroxide-based crosslinking agents but also urea-based crosslinking agents, metal alkoxide-based crosslinking agents, metal chelate-based crosslinking agents, metal salt-based crosslinking agents, carbodiimide-based crosslinking agents, oxazoline-based crosslinking agents, aziridine-based crosslinking agents, amine-based crosslinking agents, and the like may be mentioned, and isocyanate-based crosslinking agents and epoxy-based crosslinking agents are suitable. Specific examples of the isocyanate-based crosslinking agents and the epoxy-based crosslinking agents include compounds (specific examples) specifically exemplified in the paragraphs concerning the colored wafer back surface protective film. The crosslinking agent may be employed singly or in a combination of two or more kinds. Incidentally, the amount of the crosslinking agent is not particularly restricted.

In the invention, instead of the use of the crosslinking agent or together with the use of the crosslinking agent, it is also possible to perform the crosslinking treatment by irradiation with an electron beam or ultraviolet light.

The thickness of the adhesive layer 12 is not particularly restricted and, for example, is about 5 μm to 300 μm, preferably 5 μm to 80 μm, and more preferably 15 μm to 50 μm. When the thickness of the adhesive layer 12 is within the above-mentioned range, an appropriate adhesive force can be effectively exhibited. The adhesive layer 12 may be either a single layer or a multi layer.

An adhesive composition is applied over base layer 11, and this is dried (and where necessary thermal crosslinking is carried out) to form adhesive layer 12. As application method, roller coating, screen coating, gravure coating, and so forth may be cited as examples. The adhesive composition may be applied directly to base layer 11 to form adhesive layer 12 over base layer 11. The adhesive composition may be applied to release paper or the like to form adhesive layer 12, and the adhesive layer 12 may thereafter be transferred to base layer 11 to form adhesive layer 12 over base layer 11.

### —Semiconductor Backside Protective Film 3—

The two sides of semiconductor backside protective film 3 may be defined such that there is a first principal plane and a second principal plane opposite the first principal plane. The first principal plane is in contact with adhesive layer 12.

Semiconductor backside protective film 3 is colored. If this is colored, it may be possible to easily distinguish between dicing sheet 1 and semiconductor backside protective film 3. It is preferred that semiconductor backside protective film 3 be black, blue, red, or some other deep color. It is particularly preferred that this be black. The reason for this is that this will facilitate visual recognition of laser mark(s).

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

It is preferred that moisture absorptivity of semiconductor backside protective film 3 when allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. Moisture absorptivity can be controlled by means of inorganic filler content and so forth. A method for measuring moisture absorptivity of semiconductor backside protective film 3 is as follows. That is, semiconductor backside protective film 3 is allowed to stand for 168 hours in a constant-temperature/constant-humidity chamber at 85° C. and 85% RH, following which moisture absorptivity is determined from the percent weight loss as calculated based on measurements of weight before and after being allowed to stand.

Semiconductor backside protective film 3 is in an uncured state. Uncured state includes semicured state. A semicured state is preferred.

It is preferred that moisture absorptivity of the cured substance obtained when semiconductor backside protective film 3 is cured and this is allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. Moisture absorptivity can be controlled by means of inorganic filler content and so forth. A method for measuring moisture absorptivity of the cured substance is as follows. That is, the cured substance is allowed to stand for 168 hours in a constant-temperature/constant-humidity chamber at 85° C. and 85% RH, following which moisture absorptivity is determined from the percent weight loss as calculated based on measurements of weight before and after being allowed to stand.

The smaller the percentage of volatile components present in semiconductor backside protective film 3 the better. More specifically, it is preferred that the percent weight loss (fractional decrease in weight) of semiconductor backside protective film 3 following heat treatment be not greater than 1 wt %, and it is more preferred that this be not greater than 0.8 wt %. Conditions for carrying out heat treatment might, for example, be 1 hour at 250° C. Causing this to be not greater than 1 wt % will result in good laser marking characteristics. There may be reduced occurrence of cracking during the reflow operation. What is referred to as percent weight loss is the value obtained when semiconductor backside protective film 3 is thermally cured and is thereafter heated at 250° C. for 1 hour.

It is preferred that the tensile storage modulus at 23° C. of semiconductor backside protective film 3 when in an uncured state be not less than 1 GPa. Causing this to be not less than 1 GPa will make it possible to prevent semiconductor backside protective film 3 from adhering to the carrier tape. The upper limit of the range in values for the tensile storage modulus at 23° C. thereof might, for example, be 50 GPa. The tensile storage modulus at 23° C. thereof can be controlled by means of the type(s) of resin component(s) and amount(s) in which present, the type(s) of filler(s) and amount(s) in which present, and so forth. Tensile storage modulus is measured using a “Solid Analyzer RS A2” dynamic viscoelasticity measuring device manufactured by Rheometric, Inc., in tensile mode, with sample width=10 mm, sample length=22.5 mm, sample thickness=0.2 mm, frequency=1 Hz, and temperature rise rate=10° C./min in a nitrogen atmosphere at prescribed temperature (23° C.).

While there is no particular limitation with respect to the optical transmittance for a visible light beam (wavelength=380 nm to 750 nm) (visible light transmittance) of semiconductor backside protective film 3, it is for example preferred that this be within a range such that it is not greater than 20% (0% to 20%), more preferred that this be not greater than 10% (0% to 10%), and especially preferred that this be not greater than 5% (0% to 5%). If semiconductor backside protective film 3 has a visible light transmittance that is greater than 20%, there is a possibility that this will have an adverse effect on the semiconductor chip(s) due to passage of light beam(s) therethrough. Furthermore, the visible light transmittance (%) thereof can be controlled by means of the type(s) of resin component(s) and amount(s) in which present, the type(s) of colorant(s) (pigment(s), dye(s), and/or the like) and amount(s) in which present, the amount(s) in which inorganic filler(s) are present, and so forth at semiconductor backside protective film 3.

Visible light transmittance (%) of semiconductor backside protective film 3 may be measured as follows. That is, semiconductor backside protective film 3, of thickness (average thickness) 20 μm, is fabricated by itself. Next, the semiconductor backside protective film 3 is irradiated with a visible light beam of wavelength=380 nm to 750 nm (device=visible light generator manufactured by Shimadzu Corporation; product name “ABSORPTION SPECTRO PHOTOMETER”) and prescribed intensity, and intensity of the visible light beam that is transmitted therethrough is measured. Moreover, the value for visible light transmittance may be determined from the change in intensity as calculated based on measurements of a visible light beam before and after being transmitted through semiconductor backside protective film 3.

Semiconductor backside protective film 3 may be formed from a resin component, it being preferred that this be constituted from a resin composition comprising thermoplastic resin and thermosetting resin. Note that semiconductor backside protective film 3 may be constituted from a thermoplastic resin composition that does not employ thermosetting resin, or may be constituted from a thermosetting resin composition that does not employ thermoplastic resin.

It is preferred that semiconductor backside protective film 3 comprise colorant. Colorant might, for example, be dye(s) and/or pigment(s). Of these, dye(s) are preferred, and black dye(s) are more preferred.

It is preferred that colorant(s) be present in semiconductor backside protective film 3 in an amount that is not less than 0.5 wt %, more preferred that this be not less than 1 wt %, and still more preferred that this be not less than 2 wt %. It is preferred that colorant(s) be present in semiconductor backside protective film 3 in an amount that is not greater than 10 wt %, more preferred that this be not greater than 8 wt %, and still more preferred that this be not greater than 5 wt %.

Semiconductor backside protective film 3 comprises a resin component. This might, for example, be thermoplastic resin, thermosetting resin, and/or the like.

As thermoplastic resin, natural rubber; butyl rubber; isoprene rubber; chloroprene rubber; ethylene-vinyl acetate copolymer; ethylene-acrylic acid copolymer; ethylene-acrylic acid ester copolymer; polybutadiene resin; polycarbonate resin; thermoplastic polyimide resin; nylon 6, nylon 6,6, and other such polyamide resins; phenoxy resin; acrylic resin; PET (polyethylene terephthalate), PBT (polybutylene terephthalate), and other such saturated polyester resins; polyamide-imide resin; fluorocarbon resin; and the like may be cited as examples. Any one of these thermoplastic resins may be used alone, or two or more species chosen from thereamong may be used in combination. Of these, acrylic resin is preferred.

It is preferred that thermoplastic resin be present in semiconductor backside protective film 3 in an amount that is not less than 10 wt %, and it is more preferred that this be not less than 20 wt %. It is preferred that thermoplastic resin be present in semiconductor backside protective film 3 in an amount that is not greater than 70 wt %, more preferred that this be not greater than 50 wt %, and still more preferred that this be not greater than 40 wt %.

As thermosetting resin, epoxy resin, phenolic resin, amino resin, unsaturated polyester resin, polyurethane resin, silicone resin, thermosetting polyimide resin, and so forth may be cited as examples. Any one of these thermosetting resins may be used alone, or two or more species chosen from thereamong may be used in combination. As thermosetting resin, epoxy resin having low content of ionic impurities and/or other substances causing corrosion of semiconductor chips is particularly preferred. Furthermore, as curing agent for epoxy resin, phenolic resin may be preferably employed.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

It is preferred that thermosetting resin be present in semiconductor backside protective film 3 in an amount that is not less than 5 wt %, more preferred that this be not less than 10 wt %, and still more preferred that this be not less than 20 wt %. It is preferred that thermosetting resin be present in semiconductor backside protective film 3 in an amount that is not greater than 50 wt %, and it is more preferred that this be not greater than 40 wt %.

Semiconductor backside protective film 3 may comprise curing accelerator catalyst. For example, this might be amine-type curing accelerator, phosphorous-type curing accelerator, imidazole-type curing accelerator, boron-type curing accelerator, phosphorous-/boron-type curing accelerator, and/or the like.

To cause semiconductor backside protective film 3 to undergo crosslinking to a certain extent in advance, it is preferred that polyfunctional compound(s) that react with functional group(s) and/or the like at end(s) of polymer molecule chain(s) be added as crosslinking agent at the time of fabrication thereof. This will make it possible to improve adhesion characteristics at high temperatures and to achieve improvements in heat-resistance.

Semiconductor backside protective film 3 may comprise filler. Inorganic filler is preferred. This inorganic filler might, for example, be silica, clay, gypsum, calcium carbonate, barium sulfate, alumina, beryllium oxide, silicon carbide, silicon nitride, aluminum, copper, silver, gold, nickel, chromium, lead, tin, zinc, palladium, solder, and/or the like. Any one of these fillers may be used alone, or two or more species chosen from thereamong may be used in combination. Of these, silica is preferred, and fused silica is particularly preferred. It is preferred that average particle diameter of inorganic filler be within the range 0.1 μm to 80 μm. Average particle diameter of inorganic filler might, for example, be measured using a laser-diffraction-type particle size distribution measuring device.

It is preferred that filler be present in semiconductor backside protective film 3 in an amount that is not less than 10 wt %, more preferred that this be not less than 20 wt %, and still more preferred that this be not less than 30 wt %. It is preferred that filler be present in semiconductor backside protective film 3 in an amount that is not greater than 70 wt %, and it is more preferred that this be not greater than 60 wt %, and it is still more preferred that this be not greater than 50 wt %.

Semiconductor backside protective film 3 may comprise other additive(s) as appropriate. As other additive(s), flame retardant, silane coupling agent, ion trapping agent, expander, antioxidizer, antioxidant, surface active agent, and so forth may be cited as examples.

It is preferred that thickness of semiconductor backside protective film 3 be not less than 2 μm, more preferred that this be not less than 4 μm, still more preferred that this be not less than 6 μm, and particularly preferred that this be not less than 10 μm. It is preferred that thickness of semiconductor backside protective film 3 be not greater than 200 μm, more preferred that this be not greater than 160 μm, still more preferred that this be not greater than 100 μm, and particularly preferred that this be not greater than 80 μm.

### —Semiconductor Device Manufacturing Method—

As shown in FIG. 2, modified regions 41 are formed at the interior of semiconductor wafer 4P when irradiated by laser beam 100 along intended dicing lines 4L in grid-like arrangement by a beam focused on a point at the interior of semiconductor wafer 4P.

Conditions under which irradiation by laser beam 100 is carried out might, for example, be adjusted as appropriate within the following ranges of conditions.

| | |
|---|---|
| (A) Laser beam 100 | |
| Laser beam source | Semiconductor laser excited |
| | Nd:YAG laser |
| Wavelength | 1064 nm |
| Cross-sectional area of laser beam | 3.14 × 10⁻⁸ cm² |
| Oscillation mode | Q-switching pulsed |
| Cyclic frequency | 100 kHz or less |
| Pulsewidth | 1 μm or less |
| Output | 1 mJ or less |
| Laser beam quality | TEM00 |
| Polarization characteristics | Linear polarization |
| (B) Focusing lens | |
| Magnification | 100x or less |
| NA | 0.55 |
| Transmittance at wavelength of laser beam | 100% or less |
| (C) Speed of movement of stage on which | 280 mm/sec or less |
| semiconductor wafer is mounted | |

As methods for forming modified regions 41 by irradiation with laser beam 100 are described in detail at Japanese Patent No. 3408805, Japanese Patent Application Publication Kokai No. 2003-338567, and so forth, detailed description thereof here will be omitted.

As shown in FIG. 3, pre-dicing wafer 4 contains modified regions 41. Modified regions 41 are brittle as compared with other regions. Pre-dicing wafer 4 further comprises semiconductor chips 5A, 5B, 5C, . . . , 5H (hereinafter sometimes referred to collectively as “semiconductor chips 5”). The two sides of pre-dicing wafer 4 may be defined such that there is a frontside (front side) and a backside opposite the frontside. The frontside is the side on which circuitry is provided. And the backside is the side on which circuitry is not provided.

As shown in FIG. 4, pre-dicing wafer 4 is secured to semiconductor backside protective film 3 of laminated bodies 10 to form pre-expansion body 21. Pre-expansion body 21 comprises laminated bodies 10 and pre-dicing wafer 4 which is secured to semiconductor backside protective film 3.

As shown in FIG. 5, dicing ring 31 is secured to peripheral portion 12b.

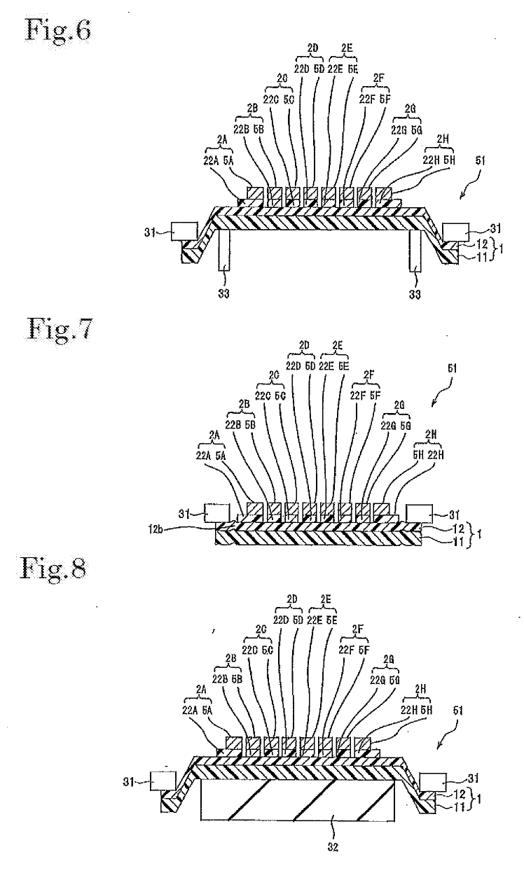

As shown in FIG. 6, dicing of pre-dicing wafer 4 is carried out, this being initiated from modified regions 41. More specifically, push-up members 33 arranged below pre-expansion body 21 are made to rise, expansion of dicing sheet 1 causing pre-dicing wafer 4 to be diced. It is preferred that push-up members 33 be made to rise at a speed that is not less than 0.1 mm/sec, and it is more preferred that this be not less than 1 mm/sec. When this is 0.1 mm/sec or greater, dicing is facilitated. It is preferred that temperature at the time that expansion is carried out be not greater than 10° C., and more preferred that this be not greater than 0° C. When this is 0° C. or less, dicing of semiconductor backside protective film 3 is facilitated. The lower limit of the range in values for temperature might, for example, be −20° C. Together with dicing of pre-dicing wafer 4, semiconductor backside protective film 3 is diced into pieces of post-dicing semiconductor backside protective film 22A, 22B, 22C, . . . , 22H (hereinafter sometimes referred to collectively as “pieces of post-dicing semiconductor backside protective film 22”).

Post-expansion body 51 comprises dicing sheet 1 and assemblies 2A, 2B, 2C, . . . , 2H (hereinafter sometimes referred to collectively as “assemblies 2”) which are secured to adhesive layer 12. Each assembly 2 comprises semiconductor chip 5 and post-dicing semiconductor backside protective film 22 which is secured to the backside of semiconductor chip 5. The two sides of semiconductor chip 5 may be defined such that there is a circuit side and a backside opposite the circuit side. All of the assemblies 2 are secured to dicing sheet 1.

As shown in FIG. 7, push-up members 33 are lowered. When push-up members 33 are lowered, this creates slack at peripheral portion 12b.

As shown in FIG. 8, suction table 32 arranged below post-expansion body 51 is raised, causing dicing sheet 1 to expand, and this expansion is maintained as suction from suction table 32 causes dicing sheet 1 to be secured to suction table 32.

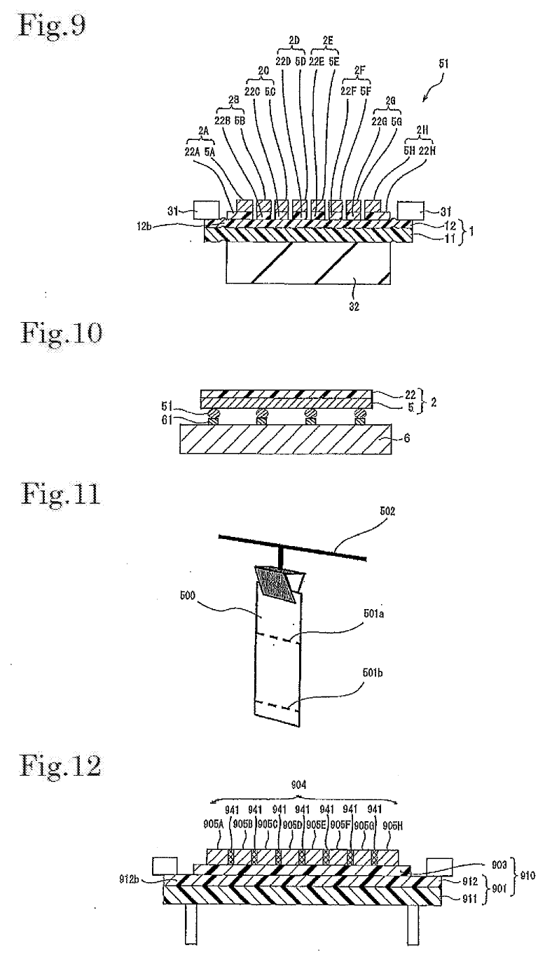

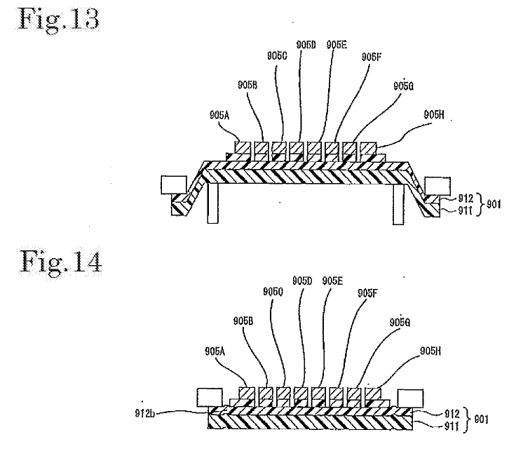

As shown in FIG. 9, with dicing sheet 1 still secured to suction table 32, suction table 32 is lowered. That is, this is de-expanded.

With dicing sheet 1 still secured to suction table 32, hot air is directed toward peripheral portion 12b. Directing hot air toward peripheral portion 12b causes slack to be removed. Because slack is removed, it is possible to prevent contact between assembly 2A and assembly 2B, assembly 2B and assembly 2C, . . . , and assembly 2G and assembly 2H. It is preferred that temperature of the hot air be not less than 220° C., and more preferred that this be not less than 250° C. When this is 220° C. or greater, contraction of peripheral portion 12b is facilitated. And it is preferred that heating be carried out such that temperature of the hot air is not greater than 400° C., and more preferred that this is not greater than 300° C. When this is 400° C. or less, it is possible to prevent damage to dicing sheet 1.

Needle(s) are used to push up assemblies 2, and assemblies 2 are detached from dicing sheet 1.

As shown in FIG. 10, the flip-chip bonding technique (flip-chip mounting technique) is employed to cause assembly 2 to be secured to object 6 to be bonded. More specifically, assembly 2 is secured to object 6 to be bonded in such fashion that the circuit side of semiconductor chip 5 is opposed to object 6 to be bonded. For example, bump 51 of semiconductor chip 5 might be made to come in contact with electrically conductive material (solder or the like) 61 of object 6 to be bonded, and while pushing this thereagainst, electrically conductive material 61 might be made to melt. There is a gap between assembly 2 and object 6 to be bonded. Height of this gap might typically be on the order of 30 μm to 300 μm. Following securing of constituent parts, it is possible to carry out cleaning of the gap and so forth.

As object 6 to be bonded, a lead frame, circuit board (wiring circuit board), or other such substrate may be employed. As material for such substrate, while there is no particular limitation with respect thereto, ceramic substrate and plastic substrate may be cited as examples. As plastic substrate, epoxy substrate, bismaleimide triazine substrate, polyimide substrate, and the like may be cited as examples.

As material for the bump and/or electrically conductive material, there is no particular limitation with respect thereto, it being possible to cite examples that include tin-lead-type metallic materials, tin-silver-type metallic materials, tin-silver-copper-type metallic materials, tin-zinc-type metallic materials, tin-zinc-bismuth-type metallic materials, and other such solders (alloys); gold-type metallic materials; and copper-type metallic materials. Note that temperature at the time of melting of electrically conductive material 61 might ordinarily be on the order of 260° C. If post-dicing semiconductor backside protective film 22 comprises epoxy resin, it will be able to withstand such temperatures.

The gap between assembly 2 and object 6 to be bonded is sealed with resin sealant. Resin sealant might ordinarily be cured by heating for 60 seconds to 90 seconds at 175° C.

As resin sealant, so long as it is a resin that has insulating characteristics (insulating resin), there is no particular limitation with respect thereto. As resin sealant, it is more preferred that this be an insulating resin that has elasticity. As resin sealant, resin compositions comprising epoxy resins and the like may be cited as examples. Furthermore, as resin sealant which is a resin composition comprising epoxy resin, the resin component thereof may, besides epoxy resin, comprise thermosetting resin other than epoxy resin (phenolic resin and/or the like), thermoplastic resin, and/or the like. Where phenolic resin is employed, note that this may also serve as curing agent for epoxy resin. Resin sealant may take the form of sheet(s), tablet(s), and/or the like.

A semiconductor device (flip-chip-mounted semiconductor device) manufactured in accordance with the foregoing method comprises object 6 to be bonded and assembly 2 secured to object 6 to be bonded.

A laser may be used to carry out marking of post-dicing semiconductor backside protective film 22 of the semiconductor device. Note that known laser marking apparatuses may be employed when carrying out laser marking. Furthermore, as laser, gas lasers, solid-state lasers, liquid lasers, and the like may be employed. More specifically, as gas laser, while there is no particular limitation with respect thereto and any known gas laser may be employed, carbon dioxide gas lasers (CO₂ lasers) and excimer lasers (ArF lasers, KrF lasers, XeCl lasers, XeF lasers, etc.) are preferred. Furthermore, as solid-state laser, while there is no particular limitation with respect thereto and any known solid-state laser may be employed, YAG lasers (Nd:YAG lasers, etc.) and YVO₄ lasers are preferred.

A semiconductor device in which semiconductor elements are mounted in a flip chip bonding manner is thinner and smaller than a semiconductor device in which semiconductor elements are mounted in a die bonding manner. For this reason, the former semiconductor device is appropriately usable for various electric instruments or electronic components, or as a component or member of these instruments or components. Specifically, an electronic instrument in which the flip-chip-bonded semiconductor device is used is, for example, the so-called “portable telephone” or “PHS”, a small-sized computer (such as the so-called “PDA” (portable data assistant), the so-called “laptop computer”, the so-called “net book (trademark)”, or the so-called “wearable computer”), a small-sized electronic instrument to which a “portable telephone” and a computer are integrated, the so-called “digital camera (trademark)”, the so-called “digital video camera”, a small-sized television, a small-sized game machine, a small-sized digital audio player, the so-called “electronic notebook”, the so-called “electronic dictionary”, the so-called electronic instrument terminal for “electronic dictionary”, a small-sized digital-type clock, or any other mobile type electronic instrument (portable electronic instrument). Of course, the electronic instrument may be, for example, an electronic instrument of a type (setup type) other than any mobile type (this instrument being, for example, the so-called “disk top computer”, a thin-type television, an electronic instrument for recording and reproduction (such as a hard disk recorder or a DVD player), a projector, or a micro machine). An electronic component in which the flip-chip-bonded semiconductor device is used, or such a component or member of an electronic instrument or electronic component is, for example, a member of the so-called “CPU”, or a member of a memorizing unit (such as the so-called “memory”, or a hard disk) that may be of various types.

### —Variation 1—

In accordance with Variation 1, semiconductor wafer 4P is secured to semiconductor backside protective film 3 of laminated bodies 10, and modified regions 41 are formed at the interior of semiconductor wafer 4P which is secured to semiconductor backside protective film 3.

### —Variation 2—

In accordance with Variation 2, dicing ring 31 is secured to dicing sheet 1 prior to formation of pre-expansion body 21.

### —Variation 3—

In accordance with Variation 3, grinding of the backside of pre-dicing wafer 4 is carried out before pre-dicing wafer 4 is secured to semiconductor backside protective film 3 of laminated bodies 10.

### —Variation 4—

Central portion 12a has a property such that it may be cured by means of an energy beam. Peripheral portion 12b also has a property such that it may be cured by means of an energy beam. At Variation 2, following the operation in which assembly 2 is formed, adhesive layer 12 is irradiated with an energy beam and pick-up of assembly 2 is carried out.

### —Variation 5—

Central portion 12a is cured by means of an energy beam. Peripheral portion 12b is also cured by means of an energy beam.

### —Variation 6—

The entire surface of one side of adhesive layer 12 is in contact with semiconductor backside protective film 3.

### —Miscellaneous—

Any of Variation 1 through Variation 6 and/or the like may be combined as desired.

A method for manufacturing a semiconductor device associated with Embodiment 1 as described above comprises Operation (A) in which pre-expansion body 21 is prepared; Operation (B) in which dicing of pre-dicing wafer 4 is carried out, this being initiated from modified regions 41 by expansion of dicing sheet 1; and Operation (C) in which peripheral portion 12b is heated following Operation (B).

### Working Examples

Although working examples are employed below to describe the present invention in more specific terms, it should be understood that the present invention, inasmuch as it does not go beyond the gist thereof, is not to be limited by the following working examples.

### Base Layer

Base Layers A through G used in the Working Examples and Comparative Examples will be described. Thicknesses of Base Layers A through G are shown in TABLE 1.

Base Layer A: Funcrare NRB#115 (ethylene-vinyl acetate copolymer film); manufactured by Gunze Limited

Base Layer B: Funcrare NRB#135 (ethylene-vinyl acetate copolymer film); manufactured by Gunze Limited

Base Layer C: PE-5 (ethylene-acrylic acid ester copolymer film); manufactured by OG Film Co., Ltd.

Base Layer D: HL Film (polyvinyl chloride film); manufactured by Lonseal Corporation

Base Layer E: PP-1 (polypropylene film); manufactured by OG Film Co., Ltd.

Base Layer F: Polypropylene (80%)-polyethylene (20%) two-layer film

Base Layer G: Polypropylene (80%)-polyethylene (20%) two-layer film

### Working Example 1

### —Fabrication of Dicing Sheet—

86.4 parts of 2-ethylhexyl acrylate (hereinafter also referred to as “2EHA”), 13.6 parts of 2-hydroxyethyl acrylate (hereinafter also referred to as “HEA”), 0.2 part of benzoyl peroxide, and 65 parts of toluene were placed in a reaction vessel equipped with a cooling tube, nitrogen feed tube, thermometer, and agitation device, and this was subjected to polymerization processing for 6 hours at 61° C. in a nitrogen gas stream to obtain Acrylic Polymer B. To the Acrylic Polymer B, 14.6 parts of 2-methacryloyloxyethyl isocyanate (hereinafter also referred to as “MOI”) was added, and this was subjected to addition reaction processing for 48 hours at 50° C. in an air stream to obtain Acrylic Polymer B′. To 100 parts of Acrylic Polymer B′, 2 parts of a polyisocyanate compound (product name “Coronate L”; manufactured by Nippon Polyurethane Co., Ltd.) and 5 parts of polymerization photoinitiator (product name “Irgacure 651”; manufactured by Ciba Specialty Chemicals Corporation) were added to obtain Adhesive Composition Solution. Adhesive Composition Solution was applied to mold-release-treated film, and this was heated and dried for 2 minutes at 120° C. to form an adhesive layer of thickness 30 μm. Base Layer A was attached to the adhesive layer, and the mold-release-treated film was detached therefrom. The dicing sheet obtained in accordance with the foregoing means comprised Base Layer A and the adhesive layer which was arranged over Base Layer A.

### —Fabrication of Semiconductor Backside Protective Film—

For every 100 parts by weight of the solids content—i.e., solids content exclusive of solvent—of acrylic-acid-ester-type polymer (Paracron W-197C; manufactured by Negami Chemical Industrial Co., Ltd) having ethyl acrylate and methyl methacrylate as principal constituents, epoxy resin in the form of 20 parts by weight (JER YL980; manufactured by Mitsubishi Chemical Corporation) and 50 parts by weight of KI-3000 manufactured by Tohto Chemical Industry Co., Ltd.), 75 parts by weight of phenolic resin (MEH7851-SS; manufactured by Meiwa Plastic Industries, Ltd.), 180 parts by weight of spherical silica (SO-25R; spherical silica having average particle diameter 0.5 μm; manufactured by Admatechs Company Limited), 10 parts by weight of dye (OILBKACK BS; manufactured by Orient Chemical Industries Co., Ltd.), and 20 parts by weight of catalyst (2PHZ; manufactured by Shikoku Chemicals Corporation) were dissolved in methyl ethyl ketone to prepare a resin composition solution having a solids concentration of 23.6 wt %. The resin composition solution was applied to mold-release-treated film (polyethylene terephthalate film of thickness 50 μm which had been subjected to silicone mold release treatment), and this was dried for 2 minutes at 130° C. In accordance with the foregoing means, a film of average thickness 20 μm was obtained. A disk-shaped piece of film (hereinafter referred to in the Working Examples as “Semiconductor Backside Protective Film”) of diameter 330 mm was cut out of the film.

### —Fabrication of Laminated Body—

A hand roller was used to apply Semiconductor Backside Protective Film to the dicing sheet to fabricate a laminated body in accordance with Working Example 1. The laminated body in accordance with Working Example 1 comprised a dicing sheet and Semiconductor Backside Protective Film which was secured to the adhesive layer of the dicing sheet.

### Working Example 2

Except for the fact that Base Layer B was used instead of Base Layer A, a method similar to that of Working Example 1 was used to fabricate a laminated body in accordance with Working Example 2.

### Working Example 3

Except for the fact that Base Layer C was used instead of Base Layer A, a method similar to that of Working Example 1 was used to fabricate a laminated body in accordance with Working Example 3.

### Working Example 4

Except for the fact that Base Layer D was used instead of Base Layer A, a method similar to that of Working Example 1 was used to fabricate a laminated body in accordance with Working Example 4.

### Comparative Example 1

Except for the fact that Base Layer E was used instead of Base Layer A, a method similar to that of Working Example 1 was used to fabricate a laminated body in accordance with Comparative Example 1.

### Comparative Example 2

Except for the fact that Base Layer F was used instead of Base Layer A, a method similar to that of Working Example 1 was used to fabricate a laminated body in accordance with Comparative Example 2.

### Comparative Example 3

Except for the fact that Base Layer G was used instead of Base Layer A, a method similar to that of Working Example 1 was used to fabricate a laminated body in accordance with Comparative Example 3.

### Evaluation 1

Evaluation of the dicing sheet was carried out as follows. Results are shown in TABLE 1.

### —Percent Shrinkage Due to Heating—

Semiconductor Backside Protective Film was detached from the laminated body to obtain the dicing sheet. Strip-shaped test piece 500 of width 25 mm and length 150 mm in the MD direction was cut from the dicing sheet. As shown in FIG. 11, test piece 500 was marked with reference line 501a and reference line 501b with a distance of 100 mm therebetween. Test piece 500 was suspended from rod 502, and a dryer was used to heat test piece 500 for 1 minute at 100° C. Following cooling, distance between reference line 501a and reference line 501b was measured, and the following formula was used to calculate percent shrinkage due to heating.

Percent shrinkage due to heating=Distance between reference lines after heating/distance between reference lines before heating×100

### —Tensile Stress at 3%—

Semiconductor Backside Protective Film was detached from the laminated body to obtain the dicing sheet. A strip-shaped measurement piece of width 25 mm and length 150 mm in the MD direction was cut from the dicing sheet. A tensile test apparatus (Autograph; manufactured by Shimadzu Corporation) was used to carry out tensile testing under conditions 23° C., 300 mm/min elongation rate, and 100 mm chuck separation, tensile stress being read at the point in time when elongation of the test piece was 3%.

### —Tensile Stress at 6%—

Semiconductor Backside Protective Film was detached from the laminated body to obtain the dicing sheet. A strip-shaped measurement piece of width 25 mm and length 150 mm in the MD direction was cut from the dicing sheet. A tensile test apparatus (Autograph; manufactured by Shimadzu Corporation) was used to carry out tensile testing under conditions 23° C., 300 mm/min elongation rate, and 100 mm chuck separation, tensile stress being read at the point in time when elongation of the test piece was 6%.

### Evaluation 2

The laminated body was used to carry out evaluation as follows. Results are shown in TABLE 1.

### —Initial Pick-Up Success Rate—

A mirror wafer (silicon mirror wafer of thickness 0.2 mm and diameter 12 inches) was compression-bonded at 80° C. to Semiconductor Backside Protective Film at the laminated body. Modified regions were formed at the interior of the mirror wafer when irradiated by a laser beam from the frontside (front side) or the backside of the mirror wafer along intended dicing lines in a grid-like arrangement (10 mm×10 mm) by a beam focused on a point at the interior of the mirror wafer. An ML300-Integration manufactured by Tokyo Seimitsu Co., Ltd., was used as laser treatment apparatus. Conditions under which laser irradiation was performed are indicated below.

| | |
|---|---|
| (A) Laser beam | |
| Laser beam source | Semiconductor laser excited |
| | Nd:YAG laser |
| Wavelength | 1064 nm |
| Cross-sectional area of laser beam | 3.14 × 10⁻⁸ cm² |
| Oscillation mode | Q-switching pulsed |
| Cyclic frequency | 100 kHz |
| Pulsewidth | 30 ns |
| Output | 20 μJ/pulse |
| Laser beam quality | TEM00 40 |
| Polarization characteristics | Linear polarization |
| (B) Focusing lens | |
| Magnification | 50x |
| NA | 0.55 |
| Transmittance at wavelength of laser beam | 60% |
| (C) Speed of movement of stage on which | 100 mm/sec |
| semiconductor substrate is mounted | |

A DDS2300 Die Separator manufactured by Disco Corporation was used to form a post-expansion sample. That is, dicing of the mirror wafer was carried out in the cool expansion unit under conditions such that expansion temperature was −15° C., expansion speed was 200 mm/sec, and expansion amount was 12 mm, and heat-shrinking of the dicing sheet was carried out in the hot expansion unit under conditions such that expansion amount was 10 mm, heating temperature was 250° C., airflow was 40 L/min, heating distance was 20 mm, and rotational speed was 3°/sec. The post-expansion sample comprised dicing sheet and a plurality of assemblies—each of which respectively comprised a silicon chip and post-dicing Semiconductor Backside Protective Film secured to the silicon chip—respectively secured to the dicing sheet. The central portion of the dicing sheet of the post-expansion sample was irradiated with ultraviolet light of intensity 400 mJ/cm². An SPA-300 Die Bonder manufactured by Shinkawa Ltd. was used under conditions such that expansion amount was 3 mm, number of needles employed was 9, needle push-up amount was 500 μm, push-up speed was 20 mm/sec, and push-up time was 1 sec to cause push-up of the assemblies and detachment thereof from the dicing sheet. 100 pick-up trials were carried out in this fashion to evaluate pick-up success rate.

—Pick-Up Success Rate after One Week—

Except for the fact that post-expansion sample was stored for one week at 23° C., a method similar to that at “Initial Pick-Up Success Rate” was used to evaluate success rate.

TABLE 1

| | | | | Evaluation 1 | | | Evaluation 2 | |
|---|---|---|---|---|---|---|---|---|
| | Base | Adhesive | Dicing | Percent | Tensile | Tensile | Initial pick-up success | Pick-up success rate after |
| | layer | layer | sheet | shrinkage | stress | stress | rate (successful trials/ | one week (successful trials/ |
| | thickness | thickness | thickness | due to | at 3% | at 6% | (successful trials + | (successful trials + |
| | (μm) | (μm) | (μm) | heating (%) | (N/mm²) | (N/mm²) | unsuccessful trials)) | unsuccessful trials)) |
| Working | 115 | 30 | 145 | 91.3 | 1.3 | 2.4 | 100/100 | 100/100 |
| Example 1 | | | | | | | | |
| Working | 135 | 30 | 165 | 93.1 | 1.3 | 2.6 | 100/100 | 100/100 |
| Example 2 | | | | | | | | |
| Working | 100 | 30 | 130 | 92.9 | 2.5 | 4.7 | 100/100 | 100/100 |
| Example 3 | | | | | | | | |
| Working | 100 | 30 | 130 | 88.3 | 4.5 | 7.1 | 100/100 | 100/100 |
| Example 4 | | | | | | | | |
| Comparative | 100 | 30 | 130 | 98.2 | 8.4 | 11.8 | 100/100 | 42/100 |
| Example 1 | | | | | | | | |
| Comparative | 100 | 30 | 130 | 98.5 | 1.8 | 3.0 | 100/100 | 27/100 |
| Example 2 | | | | | | | | |
| Comparative | 80 | 30 | 110 | 97.9 | 1.8 | 3.0 | 100/100 | 15/100 |
| Example 3 | | | | | | | | |

### EXPLANATION OF REFERENCE NUMERALS

10 Laminated body
1 Dicing sheet
11 Base layer
12 Adhesive layer
12a Central portion
12b Peripheral portion
2 Assembly
3 Semiconductor backside protective film
4P Semiconductor wafer
4l Intended dicing lines
4 Pre-dicing wafer
41 Modified regions
5 Semiconductor chip
51 Bump
6 Object to be bonded
61 Electrically conductive material
21 Pre-expansion body
22 Post-dicing semiconductor backside protective film
31 Dicing ring
32 Suction table
33 Push-up member
51 Post-expansion body
100 Laser beam

1. A laminated body comprising:
a dicing sheet comprising a base layer and an adhesive layer arranged over the base layer; and
a semiconductor backside protective film arranged over the adhesive layer;
wherein the dicing sheet is provided with a property by which application of heat thereto causes contraction thereof; and
the dicing sheet is provided with a property by which heat treatment thereof for one minute at 100° C. causes a second length in an MD direction following the heat treatment to be not greater than 95% when expressed as a percentage for which a first length in the MD direction prior to the heat treatment is taken to be 100%.

2. The laminated body according to claim 1 wherein the dicing sheet is provided with a property by which tensile stress when elongated by 3% in the MD direction at 23° C. is not less than 1 N/mm².

3. The laminated body according to claim 1 wherein the dicing sheet is provided with a property by which tensile stress when elongated by 6% in the MD direction at 23° C. is not less than 1.5 N/mm².

4. The laminated body according to claim 1 wherein thickness of the dicing sheet is 40 μm to 200 μm.

5. The laminated body according to claim 1 wherein the adhesive layer comprises a central portion that is in contact with the semiconductor backside protective film, and a peripheral portion that is arranged peripherally with respect to the central portion.

6. The laminated body according to claim 5 for use in a semiconductor device manufacturing method comprising:
an operation in which a pre-expansion body that comprises the laminated body and a pre-dicing wafer which has a modified region and which is secured to the semiconductor backside protective film is prepared;
an operation in which expansion of the dicing sheet causes dicing of the pre-dicing wafer to be carried out, the dicing being initiated from the modified region; and
an operation in which, following the operation in which the pre-dicing wafer is diced, the peripheral portion is heated.

7. A semiconductor device manufacturing method comprising:
an operation in which a pre-expansion body that comprises the laminated body according to claim 5 and a pre-dicing wafer which has a modified region and which is secured to the semiconductor backside protective film is prepared;
an operation in which expansion of the dicing sheet causes dicing of the pre-dicing wafer to be carried out, the dicing being initiated from the modified region; and
an operation in which, following the operation in which the pre-dicing wafer is diced, the peripheral portion is heated.
